(19) United States
(12) Patent Application Publication
(10) Pub. No.: US 2021/0005462 A1
(43) Pub. Date: Jan. 7, 2021

(54) SURFACE TREATMENT COMPOSITION, METHOD FOR PRODUCING SURFACE TREATMENT COMPOSITION, SURFACE TREATMENT METHOD, AND METHOD FOR PRODUCING SEMICONDUCTOR SUBSTRATE

(71) Applicant: FUJIMI INCORPORATED, Aichi (JP)

(72) Inventors: Tsutomu YOSHINO, Aichi (JP); Ayano YAMAZAKI, Aichi (JP); Shogo ONISHI, Aichi (JP); Yasuto ISHIDA, Aichi (JP)

(73) Assignee: FUJIMI INCORPORATED, Aichi (JP)

(21) Appl. No.: 16/977,522

(22) PCT Filed: Jan. 21, 2019
(86) PCT No.: PCT/JP2019/001681

§ 371 Date: Sep. 2, 2020

(30) Foreign Application Priority Data
Mar. 8, 2018 (JP) 2018-042139

(51) Int. Cl. H01L 21/306; C09G 1/02; C09K 3/14

(52) U.S. Cl. CPC H01L 21/30625; C09K 3/1463; C09G 1/02

(57) ABSTRACT

The present invention provides a composition for surface treatment that sufficiently removes the defect present on the surface of a polished object to be polished. The composition for surface treatment that includes a silicone-based compound having an HLB of more than 7 and water and is used to treat a polished object to be polished.

### TECHNICAL FIELD

The present invention relates to a composition for surface treatment, a method for manufacturing the composition for surface treatment, a method for surface treatment, and a method for manufacturing a semiconductor substrate.

### BACKGROUND ART

In recent years, as multi-layered wiring on the surface of a semiconductor substrate is developed, a so-called chemical mechanical polishing (CMP) technique of polishing and flattening a semiconductor substrate during manufacturing a device has been utilized. CMP is a method for flattening the surface of an object to be polished (material subjected to polishing) such as a semiconductor substrate or the like using a polishing composition (slurry) containing an abrasive grain such as silica, alumina, ceria, or the like, an anticorrosive, a surfactant, and the like, and the object to be polished (material subjected to polishing) is silicon, polysilicon, a silicon oxide film (silicon oxide), silicon nitride, a wire including a metal and the like, a plug, or the like.

The surface of the semiconductor substrate after the CMP process has a large amount of remaining impurities (defects). Examples of the impurities include an abrasive grain, a metal, an anticorrosive, and an organic substance such as a surfactant or the like that are derived from the polishing composition used in the CMP, a silicon-containing material that is the object to be polished, a silicon-containing material and a metal that are generated by polishing the metal wire, the plug, or the like, an organic substance such as a pad scrap or the like generated from various pads or the like, and the like.

When the surface of the semiconductor substrate is contaminated with the impurities, there is a possibility of adversely affecting the electrical characteristic of the semiconductor and reducing the reliability of the device. Therefore, it is desirable to introduce a cleaning process after the CMP process to remove the impurities from the surface of the semiconductor substrate.

As an aqueous cleaning liquid (cleaning composition) used in such a cleaning process, for example, JP 2012-74678 A (corresponding to US 2013/174,867 A) discloses a composition for cleaning a semiconductor substrate, the composition containing a polycarboxylic acid or a hydroxycarboxylic acid, a sulfonic acid type anionic surfactant, a carboxylic acid type anionic surfactant, and water. JP 2012-74678 A (corresponding to US 2013/174,867 A) describes that in order to effectively clean the contamination of the surface of a hydrophobic insulating film, it is important to improve the hydrophobic wettability using a surfactant. Furthermore, J P 2004-149732 A discloses an aqueous dispersion of hydrophilized cellulose fine particles. JP 2004-149732 A describes that when cleaning is performed using the dispersion, the cellulose fine particles enter a processed groove or the like, and a stain can be removed.

### SUMMARY OF INVENTION

However, there is a problem that the defect present on the surface of the polished object to be polished cannot be sufficiently removed by the techniques according to JP 2012-74678 A (corresponding to US 2013/174,867 A) and JP 2004-149732 A.

Therefore, an object of the present invention is to sufficiently remove the defect present on the surface of a polished object to be polished.

The present inventors have made intensive studies in view of the above-described problem. The present inventors have found that the defect on the surface of a polished object to be polished can be sufficiently removed by using a composition for surface treatment that includes a silicone-based compound having a HLB of more than 7 and water and is used to treat a polished object to be polished, and completed the present invention.

### DESCRIPTION OF EMBODIMENTS

The present invention will be described below. Note that the present invention is not limited to only the embodiments described below.

Furthermore, in the present description, the notation “(meth)acrylic” in a specific compound name means “acrylic” and “methacrylic”, and the notation “(meth)acrylate” in a specific compound name means “acrylate” and “methacrylate”.

The present invention provides a composition for surface treatment that includes a silicone-based compound having an HLB of more than 7 and water and is used to treat a polished object to be polished.

By the surface treatment with the composition having such a constitution, the impurities (defects) on the surface of a polished object to be polished can be sufficiently removed.

Note that the composition according to the present invention removes the impurities (defects) remaining on a polished object (substrate) to be polished, and in this respect, it can be said that the composition changes (treats) the state of the surface of the polished object (substrate) to be polished. Therefore, the composition is referred to as a “composition for surface treatment”.

[Polished Object to be Polished]

In the present description, the term “polished object to be polished” means an object to be polished after being polished in a polishing process. The polishing process is not particularly limited, and is preferably a CMP process.

The polished object to be polished (hereinafter, also simply referred to as “object to be cleaned”) preferably contains silicon nitride (hereinafter, also simply referred to as “SiN”), silicon oxide, or polysilicon (hereinafter, also simply referred to as “Poly-Si”). Examples of the polished object to be polished containing silicon oxide include a TEOS-type silicon oxide surface produced using tetraethyl orthosilicate as a precursor (hereinafter, also simply referred to as “TEOS”), an HDP film, an USG film, a PSG film, a BPSG film, an RTO film, and the like.

The polished object to be polished is preferably a polished semiconductor substrate, and more preferably a semiconductor substrate after the CMP process. The reason is that when the polished object to be polished is a polished semiconductor substrate, the cleaning process of a semiconductor substrate is required to be capable of removing a defect as much as possible because a defect can particularly cause the destruction of a semiconductor device.

The polished object to be polished containing silicon nitride, silicon oxide, or polysilicon is not particularly limited, and examples of such a polished object to be polished include a polished object to be polished including each of silicon nitride, silicon oxide, and polysilicon singly; a polished object to be polished being in a state that silicon nitride, silicon oxide, or polysilicon, and another material are exposed on the surface, and the like. Here, examples of the former include a silicon nitride substrate, a silicon oxide substrate, or a polysilicon substrate being a semiconductor substrate. Furthermore, regarding the latter, a material other than silicon nitride, silicon oxide, or polysilicon is not particularly limited, and examples of the material include tungsten and the like. Specific examples of the polished object to be polished include a polished semiconductor substrate having a structure in which a silicon nitride film, a silicon oxide film, or a polysilicon film is formed on tungsten; a polished semiconductor substrate having a structure in which a tungsten portion and one or more of a silicon nitride film, a silicon oxide film, or a polysilicon film are exposed, and the like.

Here, from the viewpoint of the effect of the present invention, the polished object to be polished according to one embodiment of the present invention preferably contains polysilicon or silicon oxide. The reason why the effect of the present invention is further exerted when the polished object to be polished contains polysilicon or silicon oxide is considered to be that because a silicone-based compound having an HLB of more than 7 has a high affinity for polysilicon or silicon oxide, a uniform film can be formed on the polysilicon or the silicon oxide, and a foreign material is hardly adhered to the polysilicon or the silicon oxide.

[Composition for Surface Treatment]

One embodiment of the present invention is a composition for surface treatment that includes a silicone-based compound having an HLB of more than 7 and water and is used to treat a polished object to be polished. Hereinafter, the silicone-based compound having an HLB of more than 7 is also simply referred to as a silicone-based compound. Here, the phrase “used to treat a polished object to be polished” means that the composition for surface treatment is used to change the state of the surface of the polished object to be polished by direct contact (remove impurities from the surface). Furthermore, the treatment includes rinse polishing or cleaning.

The present inventors presume the mechanism by which the present invention solves the above-described problem as follows.

As a result of the interaction of each component contained in the composition for surface treatment with the surface of the polished object to be polished or with the foreign material, the composition for surface treatment has a function to remove the foreign material on the surface of the polished object to be polished or to make the removal easy.

The surface tension of the silicone-based compound contained in the composition for surface treatment is very low, so that the wettability is very high, relative to a hydrophobic polished object to be polished even in an aqueous composition for surface treatment. Therefore, it is possible to enhance the cleaning property (to reduce the defect) for the polished object to be polished. In addition, since the silicone-based compound has a high affinity for the surface of the polished object to be polished, a uniform hydrophilic layer having a hydrophilic group facing outward is easily formed on the surface of the polished object to be polished. When the formation of the hydrophilic layer on the surface of the polished object to be polished is not uniform, the hydrophilic layer is not formed, that is, impurities (for example, a polishing pad scrap in the rinse polishing process and a residual impurity once removed by cleaning) are easily adhered to the exposed portion of the surface of the polished object to be polished, which leads to the increase in the impurities present on the surface of the polished object to be polished. On the other hand, when a uniform hydrophilic layer is formed on the surface of the polished object to be polished by the silicone-based compound, it is possible to suppress the adhesion of impurities (particularly hydrophobic components) to the surface of the polished object to be polished.

Note that the above-described mechanism is based on a presumption, and the accuracy of the presumption does not affect the technical scope of the present invention.

Hereinafter, each component contained in the composition for surface treatment will be described.

[Silicone-Based Compound]

The HLB of the silicone-based compound is more than 7. When the HLB is 7 or less, the impurities present on the surface of the polished object to be polished cannot be sufficiently removed (see Comparative Examples 2, 3 and 4 described below). When the HLB is 7 or less, the hydrophobicity of a silicone-based polymer is high, and the hydrophobicity of the layer formed on the surface of the polished object to be polished is high. As a result, it is considered that impurities are easily adhered.

From the viewpoint of the effect of the present invention, the HLB of the silicone-based polymer is preferably 7.5 or more, and more preferably 8 or more.

The upper limit of the HLB of the silicone-based compound is not particularly limited, and is generally 20 or less, and preferably 18 or less, more preferably 16 or less, still more preferably 15 or less, and still even more preferably 12 or less because the effect of the present invention is further exerted, and particularly preferably 10 or less because the number of the defects is reduced. Here, the HLB is hydrophilic-hydrophobic balance that is usually used in the field of surfactants, and is determined with a commonly used calculation equation, for example, the Griffin's equation described below: HLB value (measured value by the Griffin method)=20× sum of formula weights in hydrophilic part/molecular weight. The Griffin's equation is shown in the literature (W. C. Greiffin, J. Soc. Cosmetic Chemists, 1,311 (1949)). A larger HLB value indicates higher hydrophilicity, and a smaller HLB value indicates higher hydrophobicity. Furthermore, a numerical value of the HLB described in a catalog or the like may be used.

The silicone-based compound is a compound having a main skeleton by a siloxane bond and having a hydrophilic group. The silicone-based compound is not particularly limited, and is preferably a liquid at room temperature (25° C.), and more preferably a silicone oil. Furthermore, the kinematic viscosity of the silicone-based compound at 25° C. is not particularly limited, and in order to exert the effect of reducing the defect, the lower limit is preferably 10 mm²/s or more, more preferably 50 mm²/s or more, still more preferably 100 mm²/s or more, and still even more preferably 150 mm²/s or more. Furthermore, the upper limit is preferably 30,000 mm²/s or less, more preferably 10,000 mm²/s or less, still more preferably 5,000 mm²/s or less, still even more preferably 1,000 mm²/s or less, and particularly preferably 500 mm²/s or less because the kinematic viscosity at 25° C. is appropriate and the fluidity of the composition for surface treatment is not significantly changed. Hereinafter, the kinematic viscosity of the silicone-based compound at 25° C. is also simply referred to as the viscosity.

The silicone-based compound is preferably a polyether-modified silicone, and more preferably a polyether-modified silicone oil. The polyether-modified silicone oil may be any one of a one-end modified, a both-end modified, a side-chain modified, or a main-chain copolymerized silicone oil, and is preferably a side-chain modified silicone oil (having a structure in which a polyether chain branches off as a side chain from a silicone main chain).

The average molecular weight of the polyether-modified silicone is preferably 55,000 or less, and more preferably 40,000 or less. The average molecular weight represents the weight average molecular weight. Here, the weight average molecular weight is defined as the molecular weight expressed in terms of polystyrene detected by a differential refractometer using THF as a solvent with a GPC analyzer in which columns of TSKgel GMHxL, TSKgel G4000HxL, TSKgel G2000HxL (all trade names by Tosoh Corporation) are used.

As the polyether-modified silicone (oil), a commercially available product may be used, and examples of the commercially available product include SH8400 (HLB 8, viscosity 260 mm²/s), L-7002 (HLB 8, viscosity 1,200 mm²/s), FZ-2104 (HLB 9), FZ-77 (HLB 11, viscosity 20 mm²/s), L-7604 (HLB 11, viscosity 400 mm²/s) (that are manufactured by Toray Dow Corning); KF-6011 (HLB 14.5, viscosity 130 mm²/s), KF-6011P (HLB 14.5, viscosity 130 mm²/s), KF-6013 (HLB 10, viscosity 400 mm²/s), KF-6043 (HLB 14.5, viscosity 400 mm²/s), KF-351A (HLB 12, viscosity 70 mm²/s), KF-353 (HLB 10, viscosity 430 mm²/s), KF-354L (HLB 16, viscosity 200 mm²/s), KF-355A (HLB 12, viscosity 150 mm²/s), KF-615A (HLB 10, viscosity 920 mm²/s), KF-640 (HLB 14, viscosity 20 mm²/s), KF-642 (HLB 12, viscosity 50 mm²/s), KF-643 (HLB 14, viscosity 19 mm²/s), KF-644 (HLB 11, viscosity 38 mm²/s), KF-6024 (HLB 10, viscosity 70 mm²/s) (that are manufactured by Shin-Etsu Chemical Co., Ltd.), and the like.

Furthermore, the polyether-modified silicone (oil) used in the present invention can be easily synthesized by, for example, a method described in JP 2002-179797 A, JP 2008-1896 A, or JP 2008-1897 A, or a method in accordance with the method.

The content of the silicone-based compound is preferably 0.01% by mass or more based on the total amount of the composition for surface treatment. When the content of the silicone-based compound is 0.01% by mass or more, the effect of reducing the adhesion of impurities is further improved. From the same viewpoint, the content of the silicone-based compound is preferably 0.05% by mass or more, and more preferably 0.08% by mass or more based on the total amount of the composition for surface treatment. Furthermore, the content of the silicone-based compound is preferably 1% by mass or less based on the total amount of the composition for surface treatment. When the content of the silicone-based compound is 1% by mass or less, the content is preferable from the viewpoint of increasing the cleaning effect. From the same viewpoint, the content of the silicone-based compound is more preferably 0.8% by mass or less, still more preferably 0.5% by mass or less, and the most preferably 0.3% by mass or less based on the total amount of the composition for surface treatment.

[Dispersing Medium]

The composition for surface treatment according to one embodiment of the present invention essentially contains water as a dispersing medium (solvent). The dispersing medium has a function of dispersing or dissolving each component. The dispersing medium is more preferably only water. Furthermore, the dispersing medium may be a mixed solvent of water and an organic solvent in order to disperse or dissolve each component.

In this case, examples of the organic solvent used include water-miscible organic solvents such as acetone, acetonitrile, ethanol, methanol, isopropanol, glycerin, ethylene glycol, propylene glycol, and the like. Furthermore, these organic solvents may be used, without being mixed with water, to disperse and dissolve each component, and then mixed with water. These organic solvents can be used singly or in combination of two or more kinds thereof.

As the water, water containing impurities in an amount as small as possible is preferable from the viewpoint of suppressing the contamination of the polished object to be polished and the inhibition of the action of another component. For example, water having a total content of transition metal ions of 100 ppb or less (lower limit of 0 ppb) is preferable. Here, the purity of water can be enhanced by an operation such as removal of impurity ions using an ion exchange resin, removal of a foreign material by a filter, distillation, or the like. Specifically, as the water, for example, deionized water (ion-exchanged water), pure water, ultrapure water, distilled water, or the like is preferably used.

The content of water in the composition for surface treatment is preferably 80% by mass or more, more preferably 90% by mass or more, and still more preferably 95% by mass or more.

[Dispersant]

The composition for surface treatment according to one embodiment of the present invention preferably further contains a dispersant. The dispersant lowers the surface tension by the surface activity and contributes to the removal of a foreign material by the composition for surface treatment. Therefore, the composition for surface treatment containing the dispersant can sufficiently remove the foreign material remaining on the surface of the polished object to be polished in the surface treatment (cleaning or the like) of the polished object to be polished. Particularly, the dispersant is preferably a polymer (dispersant).

Examples of the polymer dispersant include polymer compounds having a sulfonic acid (salt) group; polymer compounds having a phosphoric acid (salt) group; polymer compounds having a phosphonic acid (salt) group; polymer compounds having a carboxylic acid (salt) group; water-soluble polymers containing a nitrogen atom such as polyvinylpyrrolidone (PVP), polyvinylimidazole (PVI), polyvinylcarbazole, polyvinylcaprolactam, polyvinylpiperidine, polyacryloylmorpholine (PACMO), and the like; polyvinyl alcohol (PVA); hydroxyethyl cellulose (HEC), and the like.

Among the polymer dispersants, the polymer compounds having a sulfonic acid (salt) group are preferable. Hereinafter, the polymer compounds having a sulfonic acid (salt) group will be described.

<Polymer Compound Having Sulfonic Acid (Salt) Group>

In the composition for surface treatment according to one embodiment of the present invention, the dispersant is preferably a polymer compound having a sulfonic acid (salt) group. The polymer compound having a sulfonic acid (salt) group (in the present description, also simply referred to as “sulfonic acid group-containing polymer”) further easily contributes to the removal of a foreign material by the composition for surface treatment. Therefore, the composition for surface treatment containing the sulfonic acid group-containing polymer has an effect of further easily removing the foreign material remaining on the surface of the polished object to be polished in the surface treatment (cleaning or the like) of the polished object to be polished.

The sulfonic acid group-containing polymer can form a micelle owing to the affinity of the portion other than the sulfonic acid (salt) group (that is, the polymer chain portion of the sulfonic acid group-containing polymer) for the foreign material (particularly the hydrophobic component). Therefore, it is considered that because the micelle is dissolved or dispersed in the composition for surface treatment, the foreign material being a hydrophobic component is also effectively removed.

Furthermore, under an acidic condition, when the surface of the polished object to be polished is cationic, an anionized sulfonic acid group is easily adsorbed on the surface of the polished object to be polished. As a result, it is considered that the surface of the polished object to be polished is in a state of being covered with the sulfonic acid group-containing polymer. Meanwhile, the sulfonic acid group of the sulfonic acid group-containing polymer is easily adsorbed to the remaining foreign material (particularly one that tends to be cationic), so that the surface of the foreign material is anionic. Therefore, the foreign material having the anionic surface electrostatically repels the anionized sulfonic acid group of the sulfonic acid group-containing polymer adsorbed on the surface of the polished object to be polished. When the foreign material is anionic, the foreign material itself electrostatically repels the anionized sulfonic acid group present on the polished object to be polished. Therefore, it is considered that the foreign material can be effectively removed by utilizing such electrostatic repulsion.

Furthermore, when the polished object to be polished is hardly charged, it is presumed that the foreign material is removed by a mechanism different from the above-described mechanism. First, it is considered that the foreign material (particularly a hydrophobic component) is in a state of being easily adhered to the hydrophobic polished object to be polished owing to the hydrophobic interaction. Here, the polymer chain portion of the sulfonic acid group-containing polymer (hydrophobic structure part) faces to the surface side of the polished object to be polished owing to the hydrophobicity of the polymer chain portion, and the anionized sulfonic acid group and the like that are a hydrophilic structure part face to the opposite side from the surface side of the polished object to be polished. As a result, it is presumed that the surface of the polished object to be polished is in a state of being covered with the anionized sulfonic acid group, and becomes hydrophilic. As a result, it is considered that the hydrophobic interaction hardly occurs between the foreign material (particularly the hydrophobic component) and the polished object to be polished, and the adhesion of the foreign material is suppressed.

Then, the silicone-based compound and the sulfonic acid group-containing polymer that are adsorbed on the surface of the polished object to be polished are easily removed by further washing with water, or the like.

Note that in the present description, the term “sulfonic acid (salt) group” means a sulfonic acid group (—SO₃H) or a group of the sulfonic acid salt (—SO₃M²; where M² represents an organic or inorganic cation).

The sulfonic acid group-containing polymer is not particularly limited as long as it has a plurality of sulfonic acid (salt) groups, and known compounds can be used. Examples of the sulfonic acid group-containing polymer include polymer compounds produced by sulfonating a base polymer compound, and polymer compounds produced by (co)polymerizing monomers having a sulfonic acid (salt) group, and the like.

More specific examples include sulfonic acid (salt) group-containing polyvinyl alcohols (sulfonic acid-modified polyvinyl alcohols), sulfonic acid (salt) group-containing polystyrenes such as polystyrene sulfonic acid, sodium polystyrene sulfonate, and the like, sulfonic acid (salt) group-containing polyvinyl acetates (sulfonic acid-modified polyvinyl acetates), sulfonic acid (salt) group-containing polyesters, copolymers of (meth)acrylic group-containing monomer-sulfonic acid (salt) group-containing monomer such as a copolymer of (meth)acrylic acid-sulfonic acid (salt) group-containing monomers and the like, and the like. The sulfonic acid group-containing polymers can be used singly or in combination of two or more kinds thereof. At least some of the sulfonic acid groups included in the polymers may be in the form of a salt. Examples of the salt include alkali metal salts such as sodium salts, potassium salts, and the like, salts of the group 2 elements such as calcium salts, magnesium salts, and the like, amine salts, ammonium salts, and the like. Particularly when the polished object to be polished is the semiconductor substrate after the CMP process, the ammonium salts are preferable from the viewpoint of removing the metal on the surface of the substrate as much as possible.

Furthermore, when the sulfonic acid group-containing polymer is a sulfonic acid group-containing polyvinyl alcohol, the saponification degree is preferably 80% or more, and preferably 85% or more (upper limit 100%) from the viewpoint of the solubility.

The weight average molecular weight of the sulfonic acid group-containing polymer is preferably 1,000 or more. When the weight average molecular weight is 1,000 or more, the effect of removing a foreign material is further enhanced. The reason is presumed that the covering property to cover the polished object to be polished or the foreign material is further enhanced, and the action of removing the foreign material from the surface of the object to be cleaned or the action of suppressing the re-adhesion of the impurities (defects) to the surface of the polished object to be polished is further improved. From the same viewpoint, the weight average molecular weight is more preferably 2,000 or more, still more preferably 5,000 or more, and the most preferably 8,000 or more.

Furthermore, the weight average molecular weight of the sulfonic acid group-containing polymer is preferably 100,000 or less. When the weight average molecular weight is 100,000 or less, the effect of removing a foreign material is further enhanced. The reason is presumed that the removing property of the sulfonic acid group-containing polymer after the cleaning process is further enhanced. From the same viewpoint, the weight average molecular weight is more preferably 50,000 or less, still more preferably 30,000 or less, even more preferably 20,000 or less, and the most preferably 15,000 or less.

The weight average molecular weight can be measured by gel permeation chromatography (GPC), and specifically can be measured by the following device and conditions.

GPC device: manufactured by SHIMADZU CORPORATION

Model: Prominence+ELSD detector (ELSD-LTII)

Column: VP-ODS (manufactured by SHIMADZU CORPORATION)

Mobile phase A: MeOH

B: acetic acid 1% aqueous solution

Flow rate: 1 mL/min

Detector: ELSD temp. 40° C., Gain 8, N₂ GAS 350 kPa

Oven temperature: 40° C.

Injection volume: 40 μL.

As the sulfonic acid group-containing polymer, a commercially available product may be used, and for example, GOHSENX (registered trademark) L-3226 and GOHSENX (registered trademark) CKS-50 manufactured by Nippon Synthetic Chemical Industry Co., Ltd., ARON (registered trademark) A-6012, A-6016A, and A-6020 manufactured by Toagosei Co., Ltd., PolyNaSS (registered trademark) PS-1 manufactured by Tosoh Organic Chemical Co., Ltd., and the like can be used.

The content (concentration) of the sulfonic acid group-containing polymer is preferably 0.01% by mass or more based on the total amount of the composition for surface treatment. When the content of the sulfonic acid group-containing polymer is 0.01% by mass or more, the effect of removing impurities (defects) is further improved. The reason is presumed that when the sulfonic acid group-containing polymer covers the polished object to be polished and the foreign material, the increased area is covered. As a result, particularly the foreign material further easily forms a micelle, so that the effect of removing the foreign material by the dissolving/dispersing of the micelle is enhanced. Furthermore, the reason is presumed that the electrostatic adsorption or repulsion effect can be more strongly exhibited by increasing the number of the sulfonic acid (salt) groups. From the same viewpoint, the content (concentration) of the sulfonic acid group-containing polymer is preferably 0.02% by mass or more based on the total amount of the composition for surface treatment. Furthermore, the content (concentration) of the sulfonic acid group-containing polymer is preferably 0.5% by mass or less based on the total amount of the composition for surface treatment. When the content of the sulfonic acid group-containing polymer is 0.5% by mass or less, the effect of removing a foreign material is further enhanced. The reason is presumed that the removing property of the sulfonic acid group-containing polymer itself after the cleaning process is enhanced. From the same viewpoint, the content of the sulfonic acid group-containing polymer is more preferably 0.3% by mass or less, still more preferably 0.2% by mass or less, and particularly preferably 0.1% by mass or less based on the total amount of the composition for surface treatment.

[pH]

The pH of the composition for surface treatment according to the present invention is preferably less than 9.0. When the pH is less than 9.0, in a case where the composition for surface treatment is used for a foreign material or an object to be cleaned having a property of being charged with a positive charge, the surface of the object to be cleaned or the surface of the foreign material can be further reliably charged with a positive charge, and an enhanced effect of removing the foreign material can be obtained owing to the electrostatic repulsion. The pH of the composition for surface treatment is preferably less than 8.0, more preferably less than 7.0, and still more preferably less than 6.0, and may be less than 4.0 or less than 3.5. Furthermore, the pH of the composition for surface treatment according to the present invention is preferably 1.5 or more, and more preferably 2.0 or more.

When the pH is to be adjusted, a pH adjusting agent is preferably used. As the pH adjusting agent, known acids, bases, or salts thereof can be used.

Specific examples of the acids that can be used as the pH adjusting agent include inorganic acids such as hydrochloric acid, sulfuric acid, nitric acid, hydrofluoric acid, boric acid, carbonic acid, hypophosphorous acid, phosphorous acid, phosphoric acid, and the like, and organic acids such as formic acid, acetic acid, propionic acid, butyric acid, pentanoic acid, 2-methylbutyric acid, hexanoic acid, 3,3-dimethyl-butyric acid, 2-ethylbutyric acid, 4-methylpentanoic acid, heptanoic acid, 2-methylhexanoic acid, octanoic acid, 2-ethylhexanoic acid, benzoic acid, hydroxyacetic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofuroic acid, methoxyacetic acid, methoxyphenylacetic acid, 2-hydroxyisobutyric acid, phenoxyacetic acid, and the like. When an inorganic acid is used as the pH adjusting agent, sulfuric acid, nitric acid, phosphorous acid, phosphoric acid, and the like are particularly preferable. Furthermore, when an organic acid is used as the pH adjusting agent, acetic acid, lactic acid, benzoic acid, hydroxyacetic acid, maleic acid, citric acid, tartaric acid, and hydroxyisobutyric acid are preferable, and maleic acid, citric acid, and tartaric acid are more preferable.

Examples of the bases that can be used as the pH adjusting agent include amines such as aliphatic amines, aromatic amines, and the like, organic bases such as ammonium solutions, quaternary ammonium hydroxides, and the like, alkali metal hydroxides such as potassium hydroxide and the like, hydroxides of the group 2 elements, amino acids such as histidine and the like, ammonia, and the like. Among the pH adjusting agents, nitric acid, ammonium solutions, and amino acids such as histidine are more preferable from the viewpoint of the ease of the pH adjustment and the further reduction of impurities.

The pH adjusting agents may be used singly or in combination of two or more kinds thereof. The addition amount of the pH adjusting agent is not particularly limited, and may be appropriately adjusted so that the composition for surface treatment has a desired pH.

[Other Additives]

The composition for surface treatment according to one embodiment of the present invention may contain (an)other additive(s) at any ratio if necessary, as long as an effect of the present invention is not impaired. However, since there is a possibility that a component other than the essential component of the composition for surface treatment according to one embodiment of the present invention will be a source of a foreign material, it is desirable to add such a component in an amount as small as possible. Therefore, it is preferable that the addition amount of the component other than the essential component is as small as possible, and it is more preferable that the component other than the essential component is not contained. Examples of another additive include abrasive grains, alkalis, antiseptic agents, dissolved gases, reducing agents, oxidizing agents, alkanolamines, and the like. Among the additives, the composition for surface treatment preferably contains substantially no abrasive grains in order to further improve the effect of removing a foreign material. Here, the phrase “containing substantially no abrasive grains” refers to a case where the content of the abrasive grains based on the entire composition for surface treatment is 0.01% by mass or less (lower limit 0% by mass), and the content is preferably 0.005% by mass or less (lower limit 0% by mass), and more preferably 0.001% by mass or less (lower limit 0% by mass).

[Effect of Removing Impurities (Defects)]

The higher the effect of removing the impurities (defects) on the surface of the polished object to be polished is, the more preferable the composition for surface treatment according to one embodiment of the present invention is. That is, when the polished object to be polished is surface-treated using the composition for surface treatment, the smaller the number of the foreign materials remaining on the surface is, the more preferable the composition for surface treatment is. Specifically, when the polished object to be polished is surface-treated using the composition for surface treatment, the number of the impurities (defects) is preferably 6,000 or less, more preferably 3,000 or less, still more preferably 2,000 or less, and particularly preferably 1,500 or less. Meanwhile, since the number of the foreign materials is preferably smaller, the lower limit of the number is not particularly limited and is substantially 100 or more.

Note that as the number of the impurities (defects), the value measured by the method described in Examples after the surface treatment by the method described in Examples is employed.

[Method for Manufacturing Composition for Surface Treatment]

The method for manufacturing the composition for surface treatment is not particularly limited. For example, the composition can be manufactured by mixing a silicone-based compound having an HLB of more than 7 and water. That is, according to another embodiment of the present invention, a method for manufacturing the composition for surface treatment, the method including mixing a silicone-based compound having an HLB of more than 7 and water, is also provided. The type, the addition amount, and the like of the silicone-based compound are as described above. Furthermore, in the method for manufacturing the composition for surface treatment according to one embodiment of the present invention, the above-described dispersant, another additive, a dispersing medium other than water, and the like may be further mixed, if necessary. The types, the addition amounts, and the like of the components are as described above.

The order of the addition and the method of the addition of each component described above are not particularly limited. The materials described above may be added all at once or separately, or stepwise or continuously. Furthermore, the method of the mixing is also not particularly limited, and a known method can be used. The method for manufacturing the composition for surface treatment preferably includes sequentially adding the silicone-based compound, the water, and the dispersant that is added if necessary, and stirring the mixture in the water. In addition, the method for manufacturing the composition for surface treatment may further include measuring and adjusting the pH of the composition for surface treatment so as to obtain a desired pH.

[Method for Surface Treatment]

Another embodiment of the present invention is a method for surface treatment, the method including treating a surface of a polished object to be polished using the composition for surface treatment.

According to the method for surface treatment according to one embodiment of the present invention, the impurities (defects) remaining on the surface of a polished object to be polished can be sufficiently removed. That is, according to another embodiment of the present invention, a method of reducing the impurities (defects) on the surface of a polished object to be polished, the method including surface-treating a polished object to be polished using the composition for surface treatment, is provided.

The method for surface treatment according to one embodiment of the present invention is performed by a method of bringing the composition for surface treatment according to the present invention into direct contact with a polished object to be polished. Examples of the method include a method of immersing the polished object to be polished in the composition for surface treatment, a method in which ultrasonic treatment is further performed, a method of pouring the composition for surface treatment over the polished object to be polished that is rotated using a pad, and the like. As the pad, a general non-woven fabric, a polyurethane, a porous fluororesin, or the like can be used without particular limitation.

Main examples of the method for surface treatment include a method by rinse polishing treatment (I) and a method by cleaning treatment (II). That is, the surface treatment according to one embodiment of the present invention is preferably performed by rinse polishing or cleaning. The rinse polishing treatment and the cleaning treatment are performed to remove the foreign material (particles, metal contamination, organic residues, a pad scrap, or the like) on the surface of a polished object to be polished to obtain a clean surface. (I) and (II) described above will be described below.

(I) Rinse Polishing Treatment

The composition for surface treatment according to the present invention is preferably used in the rinse polishing treatment. After the final polishing (finish polishing) of an object to be polished to obtain a polished object to be polished, the rinse polishing treatment is performed on a polishing table (platen) to which a polishing pad is attached for the purpose of removing the impurities (defects) on the surface of the polished object to be polished. At this time, the rinse polishing treatment is performed by bringing the composition for surface treatment according to the present invention into direct contact with the polished object to be polished. As a result, the impurities (defects) on the surface of the polished object to be polished are removed by the frictional force (physical action) by the polishing pad and the chemical action by the composition for surface treatment. Among the impurities (defects), the particles and the organic residues are particularly easily removed by the physical action. Therefore, in the rinse polishing treatment, the particles and the organic residues can be effectively removed by utilizing the friction with the polishing pad on the polishing table (platen).

Specifically, the rinse polishing treatment can be performed by setting the surface of the polished object to be polished after the polishing process on the polishing table (platen) of a polishing device, bringing the polishing pad and the polished semiconductor substrate into contact with each other, and relatively sliding the polished object to be polished and the polishing pad in contact while supplying the composition for surface treatment (rinse polishing composition) to the contact portion.

Here, the treatment conditions are not particularly limited, and for example, the pressure between the polished object to be polished and the polishing pad is preferably 0.5 to 10 psi (0.003 to 0.069 MPa). The rotation speed of the head is preferably 10 to 100 rpm. Furthermore, the rotation speed of the polishing table (platen) is preferably 10 to 100 rpm. The supply rate in the pouring is not limited, and the surface of the polished object to be polished is preferably covered with the composition for surface treatment, and the supply rate is, for example, 10 to 5,000 ml/min. Furthermore, the surface treatment time is also not particularly limited, and is preferably 5 to 180 seconds. Note that in the present invention, the surface treatment time is preferably 20 seconds or more, more preferably 30 seconds or more, and still more preferably 45 seconds or more because the increase in the number of the defects is suppressed also by long-time surface treatment. Note that the upper limit of the surface treatment time is usually 5 minutes or less.

When the treatment conditions are within such ranges, the impurities can be further removed.

The temperature of the composition for surface treatment during the rinse polishing treatment is not particularly limited, and may be usually room temperature (25° C.), or may be raised to about 40° C. or more and 70° C. or less as long as the performance is not impaired.

The rinse polishing treatment can be performed using either a single-side polishing device or a double-side polishing device. Furthermore, the polishing device preferably includes a discharge nozzle for a rinse polishing composition in addition to a discharge nozzle for a polishing composition. The operating conditions of the polishing device during the rinse polishing treatment are not particularly limited, and can be appropriately set by those skilled in the art.

(II) Cleaning Treatment

The composition for surface treatment according to the present invention is preferably used in the cleaning treatment. After the final polishing (finish polishing) of an object to be polished to obtain a polished object to be polished, or after the rinse polishing treatment, the cleaning treatment is performed for the purpose of removing the foreign material on the surface of the object to be polished. Note that the cleaning treatment and the rinse polishing treatment are classified depending on the location where the treatment is performed, and the cleaning treatment is surface treatment performed after detaching the polished object to be polished from the polishing table (platen). Also in the cleaning treatment, the impurities (defects) on the surface of the polished object to be polished can be removed by bringing the composition for surface treatment according to the present invention into direct contact with the object.

Examples of the method of the cleaning treatment include a method (i) in which in a state where the polished object to be polished is held, a cleaning brush is brought into contact with one surface or both surfaces of the polished object to be polished, and the surface of the object to be cleaned is rubbed with the cleaning brush while the composition for surface treatment is supplied to the contact portion, a method (ii) in which the polished object to be polished is immersed in the composition for surface treatment, and ultrasonic treatment or stirring is performed (dip type), and the like. In such a method, the foreign material on the surface of the object to be polished is removed by the frictional force by the cleaning brush or the mechanical force generated by the ultrasonic treatment or the stirring, and the chemical action by the composition for surface treatment.

In the method (i), the method of bringing the composition for surface treatment (cleaning composition) into contact with the polished object to be polished is not particularly limited, and examples of the method include a method by a spin in which the polished object to be polished is rotated at a high speed while the composition for surface treatment is poured on the polished object to be polished from the nozzle, a method by a spray in which the composition for surface treatment is sprayed on the polished object to be polished to clean the object, and the like.

From the viewpoint of the possibility of further efficient decontamination in a short time, the method by a spin or the method by a spray is preferably employed, and the method by a spin is more preferably employed in the cleaning treatment.

Examples of a device for such cleaning treatment include a batch cleaning device to simultaneously surface-treat a plurality of polished objects to be polished that are housed in a cassette, a single-wafer cleaning device to surface-treat one polished object to be polished that is attached to a holder, and the like. From the viewpoint of shortening the cleaning time, and the like, a method in which a single-wafer cleaning device is used is preferable.

Furthermore, Examples of the device for cleaning treatment include a polishing device including cleaning equipment in which after removing a polished object to be polished from a polishing table (platen), the object is rubbed with a cleaning brush. By using such a polishing device, the cleaning treatment of the polished object to be polished can be further efficiently performed.

As the polishing device, a general polishing device having a holder to hold a polished object to be polished, a motor in which the rotation speed can be changed, a cleaning brush, and the like can be used. As the polishing device, either a single-side polishing device or a double-side polishing device may be used. Note that when the rinse polishing process is performed after the CMP process, it is more efficient and preferable that the cleaning treatment is performed using the same device as the polishing device used in the rinse polishing process.

The cleaning brush is not particularly limited, and a resin brush is preferably used. The material of the resin brush is not particularly limited, and it is preferable to use, for example, PVA (polyvinyl alcohol). Furthermore, it is particularly preferable to use a PVA sponge as the cleaning brush.

The cleaning conditions are also not particularly limited, and can be appropriately set depending on the type of the polished object to be polished (object to be cleaned), and the type and the amount of the impurities to be removed. For example, the rotation speed of the cleaning brush is preferably 10 rpm or more and 200 rpm or less, the rotation speed of the object to be cleaned is preferably 10 rpm or more and 100 rpm or less, and the pressure applied to the object to be cleaned (polishing pressure) is preferably 0.5 psi or more and 10 psi or less. The method of supplying the composition for surface treatment to the cleaning brush is also not particularly limited, and, for example, a method of continuous supplying by a pump or the like (pouring) is employed. The supply rate is not limited, and the surfaces of the cleaning brush and the object to be cleaned are preferably always covered with the composition for surface treatment, and the supply rate is preferably 10 mL/min or more and 5,000 mL/min or less. The cleaning time is also not particularly limited, and is preferably 5 seconds or more and 180 seconds or less in the process in which the composition for surface treatment according to one embodiment of the present invention is used. When the cleaning conditions are within such ranges, the foreign material can be further effectively removed.

The temperature of the composition for surface treatment during the cleaning is not particularly limited, and may be usually room temperature (25° C.), or may be raised to about 40° C. or more and 70° C. or less as long as the performance is not impaired.

In the method (ii), the condition of the method of cleaning by immersion is not particularly limited, and a known method can be used.

Cleaning with water may be performed before, after, or before and after the cleaning treatment by the method (i) or (ii).

Furthermore, the polished object to be polished (object to be cleaned) after the cleaning is preferably dried by removing water droplets adhering to the surface with a spin dryer or the like. Furthermore, the surface of the object to be cleaned may be dried by air blow drying.

[Method for Manufacturing Semiconductor Substrate]

The method for surface treatment according to one embodiment of the present invention can be suitably applied when the polished object to be polished is a polished semiconductor substrate. That is, according to another embodiment of the present invention, a method for manufacturing a semiconductor substrate, the method including treating a surface of a polished object to be polished by the method for surface treatment wherein the polished object to be polished is a polished semiconductor substrate, is also provided.

The details of the semiconductor substrate to which such a method for manufacturing is applied are as described in the description of the polished object to be polished that is surface-treated with the composition for surface treatment.

Furthermore, the method for manufacturing a semiconductor substrate is not particularly limited as long as the method include a process of surface-treating the surface of a polished semiconductor substrate using the composition for surface treatment according to one embodiment of the present invention, or a process of surface-treating by the method for surface treatment according to one embodiment of the present invention (surface treatment process). Examples of such a method for manufacturing include a method including a polishing process and a cleaning process in order to form a polished semiconductor substrate. Furthermore, another example is a method including, in addition to the polishing process and the cleaning process, a rinse polishing process between the polishing process and the cleaning process. Hereinafter, each of the processes will be described.

<Polishing Process>

The polishing process that can be included in the method for manufacturing a semiconductor substrate is a process of polishing a semiconductor substrate to form a polished semiconductor substrate.

The polishing process is not particularly limited as long as it is a process of polishing a semiconductor substrate, and is preferably a chemical mechanical polishing (CMP) process. Furthermore, the polishing process may include a single step or a plurality of steps. Examples of the polishing process including a plurality of steps include a process in which after a preliminary polishing step (rough polishing step), a finish polishing step is performed, a process in which after a primary polishing step, a secondary polishing step is performed once or twice or more and then a finish polishing step is performed, and the like. The surface treatment process in which the composition for surface treatment according to the present invention is used is preferably performed after the finish polishing step.

As the polishing composition, a known polishing composition can be appropriately used depending on the characteristic of the semiconductor substrate. The polishing composition is not particularly limited, and, for example, a polishing composition containing an abrasive grain, an acid salt, a dispersing medium, and an acid, and the like can be preferably used. Specific examples of such a polishing composition include a polishing composition containing sulfonic acid-modified colloidal silica, water, and maleic acid, and the like.

As the polishing device, a general polishing device can be used having a holder to hold an object to be polished, a motor in which the rotation speed can be changed, and the like that are attached to the polishing device, and having a polishing table to which a polishing pad (polishing cloth) can be adhered. As the polishing device, either a single-side polishing device or a double-side polishing device may be used.

As the polishing pad, a general non-woven fabric, a polyurethane, a porous fluororesin, or the like can be used without particular limitation. The polishing pad is preferably grooved so that a polishing liquid is gathered in the groove.

The polishing conditions are also not particularly limited, and, for example, the rotation speed of the polishing table or the rotation speed of the head (carrier) is preferably 10 rpm or more and 100 rpm or less, and the pressure applied to the object to be polished (polishing pressure) is preferably 0.5 psi or more and 10 psi or less. The method of supplying the polishing composition to the polishing pad is also not particularly limited, and, for example, a method of continuous supplying by a pump or the like (pouring) is employed. The supply rate is not limited, and the surface of the polishing pad is preferably always covered with the polishing composition, and the supply rate is preferably 10 mL/min or more and 5,000 mL/min or less. The polishing time is also not particularly limited, and is preferably 5 seconds or more and 180 seconds or less in the process in which the polishing composition is used.

<Surface Treatment Process>

The term “surface treatment process” refers to a process of reducing the foreign material on the surface of a polished object to be polished using the composition for surface treatment according to the present invention. In the method for manufacturing a semiconductor substrate, the cleaning process as a surface treatment process may be performed after the rinse polishing process, or only the rinse polishing process or only the cleaning process may be performed.

(Rinse Polishing Process)

The rinse polishing process may be provided between the polishing process and the cleaning process in the method for manufacturing a semiconductor substrate. The rinse polishing process is a process of reducing the foreign material on the surface of a polished object to be polished (polished semiconductor substrate) by the method for surface treatment (method for rinse polishing treatment) according to one embodiment of the present invention.

As the devices such as the polishing device and the polishing pad and the polishing conditions, the same devices and conditions as in the polishing process can be applied, except that the composition for surface treatment according to the present invention is supplied instead of the polishing composition.

The details of the method of rinse polishing used in the rinse polishing process are as described in the description of the rinse polishing treatment.

(Cleaning Process)

The cleaning process may be provided after the polishing process or the rinse polishing process in the method for manufacturing a semiconductor substrate. The cleaning process is a process of reducing the foreign material on the surface of a polished object to be polished (polished semiconductor substrate) by the method for surface treatment (method of cleaning) according to one embodiment of the present invention.

The details of the method of cleaning used in the cleaning process are as described in the description of the method of cleaning.

### EXAMPLES

The present invention will be described in more detail with reference to Examples and Comparative Examples described below. However, the technical scope of the present invention is not limited only to Examples described below. Note that unless otherwise specified, “%” and “parts” mean “% by mass” and “parts by mass”, respectively. Furthermore, in Examples described below, unless otherwise specified, the operation was carried out under the conditions of room temperature (20 to 25° C.)/a relative humidity of 40 to 50% RH.

<Preparation of Composition for Surface Treatment>

### Example 1: Preparation of Composition for Surface Treatment A-1

Based on 100 parts by mass of an entire composition, 1.0 part by mass of a maleic acid aqueous solution having a concentration of an organic acid of 30% by mass (0.3 part by mass of maleic acid), 0.1 part by mass of SH8400 (manufactured by Toray Dow Corning, a polyether-modified silicone oil) (HLB 8, viscosity 260 mm²/s) as a silicone-based compound, 0.025 part by mass of polystyrene sulfonic acid (weight average molecular weight 10,000) as a polymer dispersant, and 98.875 parts by mass of water (deionized water) were mixed to prepare a composition for surface treatment A-1.

Regarding the composition for surface treatment A-1 (liquid temperature: 25° C.), the pH determined by a pH meter (manufactured by HORIBA, Ltd., product name: LAQUA (registered trademark)) was 2.0.

### Example 2: Preparation of Composition for Surface Treatment A-2

A composition for surface treatment A-2 was prepared in the same manner as in Example 1, except that instead of SH8400 (manufactured by Toray Dow Corning) (HLB 8), L-7002 (manufactured by Toray Dow Corning, a polyether-modified silicone oil) (HLB 8, viscosity 1,200 mm²/s) was used as a silicone-based compound. Regarding the composition for surface treatment A-2 (liquid temperature: 25° C.), the pH determined in the same manner as in Example 1 was 2.0.

### Example 3: Preparation of Composition for Surface Treatment A-3

A composition for surface treatment A-3 was prepared in the same manner as in Example 1, except that instead of SH8400 (manufactured by Toray Dow Corning) (HLB 8), L-7604 (manufactured by Toray Dow Corning, a polyether-modified silicone oil) (HLB 11, viscosity 400 mm²/s) was used as a silicone-based compound. Regarding the composition for surface treatment A-3 (liquid temperature: 25° C.), the pH determined in the same manner as in Example 1 was 2.0.

### Example 4: Preparation of Composition for Surface Treatment A-4

A composition for surface treatment A-4 was prepared in the same manner as in Example 1, except that instead of SH8400 (manufactured by Toray Dow Corning) (HLB 8), KF-6043 (manufactured by Shin-Etsu Chemical Co., Ltd., PEG-10 dimethicone) (HLB 14.5, viscosity 400 mm²/s) was used as a silicone-based compound. Regarding the composition for surface treatment A-4 (liquid temperature: 25° C.), the pH determined in the same manner as in Example 1 was 2.0.

### Example 5: Preparation of Composition for Surface Treatment A-5

A composition for surface treatment A-5 was prepared in the same manner as in Example 1, except that instead of SH8400 (manufactured by Toray Dow Corning) (HLB 8), KF-6011 (manufactured by Shin-Etsu Chemical Co., Ltd., PEG-11 methyl ether dimethicone) (HLB 14.5, viscosity 130 mm²/s) was used as a silicone-based compound. Regarding the composition for surface treatment A-5 (liquid temperature: 25° C.), the pH determined in the same manner as in Example 1 was 2.0.

### Comparative Example 1: Preparation of Composition for Surface Treatment C-1

A composition for surface treatment C-1 was prepared in the same manner as in Example 1, except that no silicone-based compound was used. Regarding the composition for surface treatment C-1 (liquid temperature: 25° C.), the pH determined in the same manner as in Example 1 was 2.0.

### Comparative Example 2: Preparation of Composition for Surface Treatment C-2

A composition for surface treatment C-2 was prepared in the same manner as in Example 1, except that instead of SH8400 (manufactured by Toray Dow Corning) (HLB 8), FZ-2203 (manufactured by Toray Dow Corning, a polyether-modified silicone oil) (HLB 2, viscosity 4,500 mm²/s) was used as a silicone-based compound. Regarding the composition for surface treatment C-2 (liquid temperature: 25° C.), the pH determined in the same manner as in Example 1 was 2.0.

### Comparative Example 3: Preparation of Composition for Surface Treatment C-3

A composition for surface treatment C-3 was prepared in the same manner as in Example 1, except that instead of SH8400 (manufactured by Toray Dow Corning) (HLB 8), SH8700 (manufactured by Toray Dow Corning, a polyether-modified silicone oil) (HLB 6, viscosity 1,200 mm²/s) was used as a silicone-based compound. Regarding the composition for surface treatment C-3 (liquid temperature: 25° C.), the pH determined in the same manner as in Example 1 was 2.0.

### Comparative Example 4: Preparation of Composition for Surface Treatment C-4

A composition for surface treatment C-4 was prepared in the same manner as in Example 1, except that instead of SH8400 (manufactured by Toray Dow Corning) (HLB 8), KF-6012 (manufactured by Shin-Etsu Chemical Co., Ltd., PEG/PPG-20/22 butyl ether dimethicone) (HLB 7, viscosity 1,500 mm²/s) was used as a silicone-based compound. Regarding the composition for surface treatment C-4 (liquid temperature: 25° C.), the pH determined in the same manner as in Example 1 was 2.0.

<Evaluation>

<Preparation of Polished Object to be Polished (Object to be Subjected to Surface Treatment)>

A polished polysilicon substrate (polished semiconductor substrate) after being polished by the chemical mechanical polishing (CMP) process described below was prepared as an object to be subjected to surface treatment (polished object to be polished).

[CMP Process]

A polysilicon substrate and a TEOS substrate (200 mm wafer) that are semiconductor substrates were polished under each condition described below using a polishing composition M (composition; 4% by mass of sulfonic acid-modified colloidal silica (produced by the method described in “Sulfonic acid-functionalized silica through quantitative oxidation of thiol groups”, Chem. Commun. 246-247 (2003), average primary particle size 30 nm, average secondary particle size 60 nm), 0.018% by mass of a maleic acid aqueous solution having a concentration of 30% by mass, solvent:water).

(Polishing Device and Polishing Conditions)

Polishing device: MirraMesa manufactured by Applied Materials, Inc.

Polishing pad: a hard polyurethane pad IC1010 manufactured by Nitta Haas Incorporated

Polishing pressure: 2.0 psi (1 psi=6,894.76 Pa, the same below)

Polishing table rotation speed: 60 rpm

Head rotation speed: 60 rpm

Supply of polishing composition: pouring

Polishing composition supply rate: 100 mL/min

Polishing time: 60 seconds

[Rinse Polishing (Surface Treatment) Process]

The polished polysilicon substrate and TEOS substrate after being polished by the CMP process were subjected to rinse polishing under the conditions described below using each composition for surface treatment.

(Rinse Polishing Device and Rinse Conditions)

Polishing device: MirraMesa manufactured by Applied Materials, Inc.

Polishing pad: a hard polyurethane pad IC1010 manufactured by Nitta Haas Incorporated

Polishing pressure: 1.0 psi

Polishing table rotation speed: 60 rpm

Head rotation speed: 60 rpm

Supply of composition for surface treatment: pouring

Composition for surface treatment supply rate: 100 mL/min

Surface treatment (rinse polishing) time: 60 seconds

<Evaluation>

The following items of each polished object to be polished after the rinse polishing process were measured and evaluated. All the evaluation results are shown in Table 1.

[Evaluation of Total Number of Defects]

The total number of the defects having a size of 0.13 μm or more was measured in the polished object to be polished after the cleaning process. SP-2 manufactured by KLA-Tencor Corporation was used to measure the total number of the defects. On one side of the polished object to be polished, the portion having a width of 5 mm from the outer periphery edge was excluded, and the remaining portion was measured.

The evaluation results of each composition for surface treatment are shown in Table 1 below. The table shows the number of the defects after the surface treatment of the polished polysilicon substrate in the column of “Number of defects of Poly-Si”, and the number of the defects after the surface treatment of the polished TEOS substrate in the column of “Number of defects of TEOS”.

TABLE 1

| | Composition | | | | | | Number of | Number |
|---|---|---|---|---|---|---|---|---|
| | for surface | Silicone oil | | Viscosity | Polymer | | defects of | of defects |
| | treatment | (product name) | HLB | (mm²/s) | dispersant | Acid | Poly-Si | of TEOS |
| Example 1 | A-1 | SH8400 | 8 | 260 | Polystyrene | Maleic | 503 | 397 |
| | | (manufactured by | | | sulfonic | acid | | |
| | | Toray Dow Corning) | | | acid | | | |
| Example 2 | A-2 | L-7002 | 8 | 1200 | Polystyrene | Maleic | 669 | 442 |
| | | (manufactured by | | | sulfonic | acid | | |
| | | Toray Dow Corning) | | | acid | | | |
| Example 3 | A-3 | L-7604 | 11 | 400 | Polystyrene | Maleic | 709 | 538 |
| | | (manufactured by | | | sulfonic | acid | | |
| | | Toray Dow Corning) | | | acid | | | |
| Example 4 | A-4 | KF-6043 | 14.5 | 400 | Polystyrene | Maleic | 693 | 502 |
| | | (manufactured by | | | sulfonic | acid | | |
| | | Shin-Etsu Chemical | | | acid | | | |
| | | Co., Ltd.) | | | | | | |
| Example 5 | A-5 | KF-6011 | 14.5 | 130 | Polystyrene | Maleic | 771 | 894 |
| | | (manufactured by | | | sulfonic | acid | | |
| | | Shin-Etsu Chemical | | | acid | | | |
| | | Co., Ltd.) | | | | | | |
| Comparative | C-1 | None | — | — | Polystyrene | Maleic | 5671 | 3972 |
| Example 1 | | | | | sulfonic | acid | | |
| | | | | | acid | | | |
| Comparative | C-2 | FZ-2203 | 2 | 4500 | Polystyrene | Maleic | 7893 | 4122 |
| Example 2 | | (manufactured by | | | sulfonic | acid | | |
| | | Toray Dow Corning) | | | acid | | | |
| Comparative | C-3 | SH8700 | 6 | 1200 | Polystyrene | Maleic | 4321 | 3371 |
| Example 3 | | (manufactured by | | | sulfonic | acid | | |
| | | Toray Dow Corning) | | | acid | | | |
| Comparative | C-4 | KF-6012 | 7 | 1200 | Polystyrene | Maleic | 3984 | 4976 |
| Example 4 | | (manufactured by | | | sulfonic | acid | | |
| | | Shin-Etsu Chemical | | | acid | | | |
| | | Co., Ltd.) | | | | | | |

As is clear from Table 1 above, in the case of the composition for surface treatment in Examples, the number of the defects after the surface treatment of the polysilicon substrate or the TEOS substrate was 900 or less. Meanwhile, in the case of the composition for surface treatment in Comparative Examples, the number of the defects after the surface treatment was more than 3,000.

Therefore, it is found that when the silicone-based compound having an HLB of more than 7 is used in the composition for surface treatment, the effect of removing the defects on the surface of the polished object to be polished is extremely high.

Furthermore, the present application is based on JP 2018-42139 A filed on Mar. 8, 2018, and the disclosure content of the patent application is incorporated by reference in its entirety.

1. A composition for surface treatment comprising: a silicone-based compound having an HLB of more than 7; and water, the composition used to treat a polished object to be polished.

2. The composition for surface treatment according to claim 1, further comprising a dispersant.

3. The composition for surface treatment according to claim 2, wherein the dispersant is a polymer.

4. The composition for surface treatment according to claim 1, the composition containing substantially no abrasive grain.

5. The composition for surface treatment according to claim 1, wherein the polished object to be polished contains polysilicon or silicon oxide.

6. A method for manufacturing the composition for surface treatment according to claim 1, the method comprising mixing a silicone-based compound having an HLB of more than 7 and water.

7. A method for surface treatment, the method comprising treating a surface of a polished object to be polished using the composition for surface treatment according to claim 1.

8. The method for surface treatment according to claim 7, wherein the surface treatment is performed by a rinse polishing treatment or a cleaning treatment.

9. A method for manufacturing a semiconductor substrate, the method comprising treating a surface of a polished object to be polished by the method for surface treatment according to claim 7,
wherein the polished object to be polished is a polished semiconductor substrate.
